(19) United States
(12) Patent Application Publication
(10) Pub. No.: US 2016/0035604 A1
(43) Pub. Date: Feb. 4, 2016

(54) Substrate Processing Device and Substrate Processing Device-Use Coupling Member

(71) Applicant: TOKYO ELECTRON LIMITED, Tokyo (JP)

(72) Inventor: Tsutomu HIROKI, Nirasaki-shi, Yamanashi (JP)

(73) Assignee: TOKYO ELECTRON LIMITED, Tokyo (JP)

(21) Appl. No.: 14/775,753

(22) PCT Filed: Jan. 31, 2014
(86) PCT No.: PCT/JP2014/052815

§ 371 Date: Sep. 14, 2015

(30) Foreign Application Priority Data
Mar. 27, 2013 (JP) 2013-066104

(51) Int. Cl. H01L 21/67; B25J 11/00; H01L 21/677

(52) U.S. Cl. CPC H01L 21/67196; H01L 21/67742; B25J 11/0095

(57) ABSTRACT

A substrate processing device to suppress contamination inside a transfer chamber, suppresses heat conduction from a processing chamber to a transfer chamber with a simple structure, and reduce cost is disclosed. The substrate processing device includes a process module maintained in a vacuum atmosphere to perform plasma process on a wafer, a transfer module maintained in a vacuum atmosphere to transfer the wafer into/out of the process module; and a coupling member connects the process module and the transfer module. The coupling member has a metal frame member interposed between a vacuum chamber of the process module and a transfer module housing part, and that separates the transfer module having a vacuum atmosphere and an exterior of the substrate processing device having an air atmosphere; and a plurality of spherical members that is in contact with an inner surface of the frame member inside the frame member.

### TECHNICAL FIELD

The present disclosure generally relates to a substrate processing device and a coupling member for the substrate processing device; particularly to the substrate processing device for processing a substrate such as a semiconductor wafer and so forth under vacuum atmosphere.

### BACKGROUND

A substrate processing device which performs processes such as plasma etching on the semiconductor wafers (hereinafter, referred to as “wafer”) and so forth includes a processing chamber for processing the wafer at a high temperature under a vacuum atmosphere of a predetermined degree of vacuum. A transfer chamber, which is connected to the processing chamber and includes a wafer transfer robot to transfer the wafer to/from the processing chamber, is maintained in a vacuum atmosphere of a predetermined degree of vacuum.

Here, if the temperature of the transfer chamber becomes high by heat conduction from the processing chamber, grease applied to a sliding part of the transfer robot is evaporated, whereby it causes problems which lead to interference with the movement of the transfer robot, progress of deterioration due to wear, and generation of particles. Therefore, a structure has been used to suppress heat conduction from a processing chamber to a transfer chamber by interposing a coupling member, which is made of resin material with low thermal conductivity (e.g., amorphous thermoplastic Poly Ether Imide (PEI) resin, etc.), between the processing chamber and the transfer chamber. Moreover, a structure for suppressing thermal conduction from a processing chamber to a transfer chamber by interposing a coupling member, in which the interior of the coupling member is maintained in a vacuum, between the processing chamber and the transfer chamber (for example, see Patent Document 1).

### PRIOR ART DOCUMENTS

### Patent Documents

Patent Document 1: Japanese Patent Application Publication No. 2005-191494

However, if heat-resistant resin material such as PEI resin and so forth is used as the coupling member, there is problem in that because of the hygroscopic of the resin material, gas emission such as moisture and so forth released from the resin material pollutes the transfer chamber or the processing chamber; or heat-resistance is not sufficient. Moreover, there is a problem in that: heat-resistant resin material such as PEI resin and so forth is expensive; or there is a small degree of freedom in shape design (e.g., fixing to the processing chamber or the transfer chamber in a thin portion) due to low mechanical strength.

On the other hand, if the coupling member in which the interior of the coupling member is maintained in a vacuum, metallic material having a certain thickness is needed in order to secure the strength of the coupling member. However, since a metallic material generally has excellent heat conductivity, even though the interior of the coupling member is in a vacuum, it is difficult to suppress heat transfer to a sufficiently small amount from a side of the processing chamber to a side of the transfer chamber due to the heat conduction through the metallic material itself which constitutes the coupling member.

### SUMMARY

The present disclosure describes a substrate processing device and a coupling member for the substrate processing device which reduces contamination of the interior of the transfer chamber, and reduces heat conduction from a side of the processing chamber to a side of the transfer chamber with a simple structure, thereby realizing cost reduction.

According to an embodiment of the present disclosure, there is provided a substrate processing device including: a processing chamber maintained in a vacuum atmosphere to process a substrate; a transfer chamber configured to transfer the substrate to/from the processing chamber; and a coupling member configured to connect the processing chamber and the transfer chamber. The coupling member includes: a metallic frame member interposed and supported between a housing part of the processing chamber and a housing part of the transfer chamber, and that separates an interior of the transfer chamber having a vacuum atmosphere and an exterior of the substrate processing device having an air atmosphere; and a plurality of spherical members that are in contact with an inner surface of the frame member in an interior of the frame member, the plurality of spherical members made of metal or ceramics.

In the present disclosure, in some embodiments, a temperature of the processing chamber is higher than room temperature.

In the present disclosure, in some embodiments, the frame member is made of stainless steel having a thickness ranging from 0.5 to 1 mm.

In the present disclosure, in some embodiments, the spherical members are zirconia balls or stainless balls.

In the present disclosure, in some embodiments, in the frame member, a surface exposed to the vacuum atmosphere of the interior of the transfer chamber is a mirror surface.

In the present disclosure, in some embodiments, in the coupling member, the spherical members are exposed to the vacuum atmosphere of the interior of the transfer chamber.

In the present disclosure, in some embodiments, in the coupling member, the spherical members are exposed to the air atmosphere of the exterior of the substrate processing device.

In the present disclosure, in some embodiments, the coupling member includes a lid member that encloses the spherical members in the frame member; the frame member comprises an exhaust port to evacuate a space enclosing the spherical member; and the space enclosing the spherical members has a predetermined degree of vacuum.

In the present disclosure, in some embodiments, the frame member comprises a flange portion fixed to the processing chamber and the transfer chamber by bolts.

According to an embodiment of the present disclosure, there is provided a coupling member for a substrate processing device including a processing chamber maintained in a vacuum atmosphere to process a substrate, a transfer chamber maintained in vacuum atmosphere to transfer the substrate to/from the processing chamber, the coupling member coupling the processing chamber and the transfer chamber. The coupling member includes: a metallic frame member interposed and supported between a housing part of the processing chamber and a housing part of the transfer chamber, and that separates an interior of the transfer chamber having a vacuum atmosphere and an exterior of the substrate processing device having an air atmosphere; and a plurality of spherical members that are in contact with an inner surface of the frame member in an interior of the frame member.

In the present disclosure, in some embodiments, the frame member is made of stainless steel having a thickness ranging from 0.5 to 1 mm.

In the present disclosure, in some embodiments, the spherical members are zirconia balls or stainless balls.

### Effect of Some Embodiments of the Present Disclosure

In the substrate processing device according to an embodiments of the present disclosure, a coupling member connecting a processing chamber and a transfer chamber includes: a metallic frame member that is interposed and supported between a housing part of the processing chamber and a housing part of the transfer chamber; and that separates an interior of the transfer chamber having a vacuum atmosphere and an exterior of the substrate processing device having an air atmosphere; and a plurality of spherical members made of metal or ceramics and that are in contact with an inner surface of the frame member in interior of the frame member.

For that reason, even though the frame member is made of thin metallic member, the mechanical strength of the entire coupling member can be secured. Moreover, heat conduction from the processing chamber to the transfer chamber occurs mainly through the frame member. Since the frame member is thin, heat transfer from the processing chamber to the transfer chamber can be suppressed at a small amount, whereby an increase in temperature of the transfer chamber can be suppressed. Further, if an increase in temperature of the transfer chamber is suppressed, evaporation of grease and so forth applied to the sliding part of a transfer device arranged in the transfer chamber is suppressed, whereby contamination of the interior of the transfer chamber is suppressed. In addition, wear of the sliding part can be suppressed which results in smoothly operating the transfer device and extending the life of the sliding part. At the same time, generation of particles can be suppressed.

Since the frame member and/or the spherical members made of metal or ceramics, which constitute the coupling member, are configured to be exposed to a vacuum atmosphere of the interior of the transfer chamber, whereby it is possible to suppress the amount of gas emission such as moisture and so forth released from the frame member and the spherical members (the frame member and the spherical members are made of a metallic member or ceramic member which has lower water adsorption than resin material) to the vacuum atmosphere of the transfer chamber at a small amount, whereby contamination of the interior of the transfer chamber can be suppressed. Moreover, since a metal material, which is easy to manufacture and inexpensive, is used as the frame member, and readymade products can be used as the spherical members, it is possible to reduce cost with respect to the coupling member made of conventional resin material (PEI resin and so forth).

### BRIEF DESCRIPTION OF THE DRAWINGS

FIG. 1 is a plan view schematically illustrating a configuration of a substrate processing device according to an embodiment of the present disclosure.

FIG. 2A is a cross-sectional view schematically illustrating a structure of a coupling part between a transfer module and a process module, which is included in the substrate processing device in FIG. 1.

FIG. 2B is an enlarged view of a region A indicated in FIG. 2A.

FIG. 3A is a perspective view schematically illustrating the structure of the coupling member illustrated in FIGS. 2A and 2B.

FIG. 3B is an exploded perspective view schematically illustrating a frame member which constitutes the coupling member illustrated in FIGS. 2A to 2B.

FIG. 4A is a partial perspective view and a side view of a coupling member according to a first modified example of the coupling member according to the embodiment of the present disclosure.

FIG. 4B is a partial perspective view and a side view of a comparative example of the coupling member according to the embodiment of the present disclosure.

FIG. 5 is a partial perspective view of a second modified example of the coupling member according to the embodiment of the present disclosure.

FIG. 6A is a partial cross-sectional view of a third modified example of the coupling member according to the embodiment of the present disclosure.

FIG. 6B is a partial cross-sectional view of a fourth modified example of the coupling member according to the embodiment of the present disclosure.

### DETAILED DESCRIPTION

Hereinafter, embodiments of the present disclosure will be described with reference to the drawings. Here, a semiconductor wafer (wafer) as a substrate will be dealt with, and a substrate processing device, which performs a plasma process which is an example of a processes performed with respect to the wafer under a vacuum atmosphere, will be dealt with.

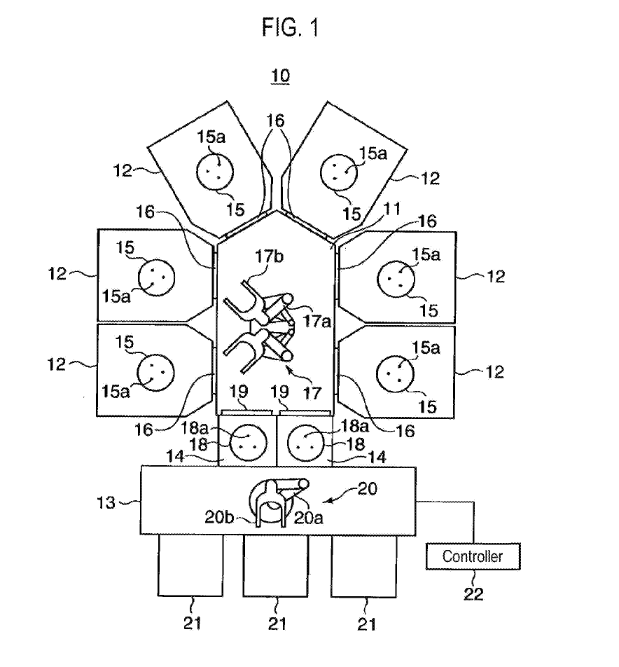

FIG. 1 is a plan view schematically illustrating a configuration of a substrate processing device according to an embodiment of the present disclosure. A substrate processing device 10 is configured to perform a plasma process on a single wafer W (one sheet by one sheet). Specifically, the substrate processing device 10 includes a transfer module 11 (substrate transfer chamber) which has a substantially pentagon shape in a plan view, six process modules 12 (substrate processing chamber) which are radially arranged around the transfer module 11 and are connected to the transfer module 11, a loader module 13 which is arranged to face the transfer module 11, and two load lock modules 14 (air/vacuum switching system) interposed between the transfer module 11 and the loader module 13.

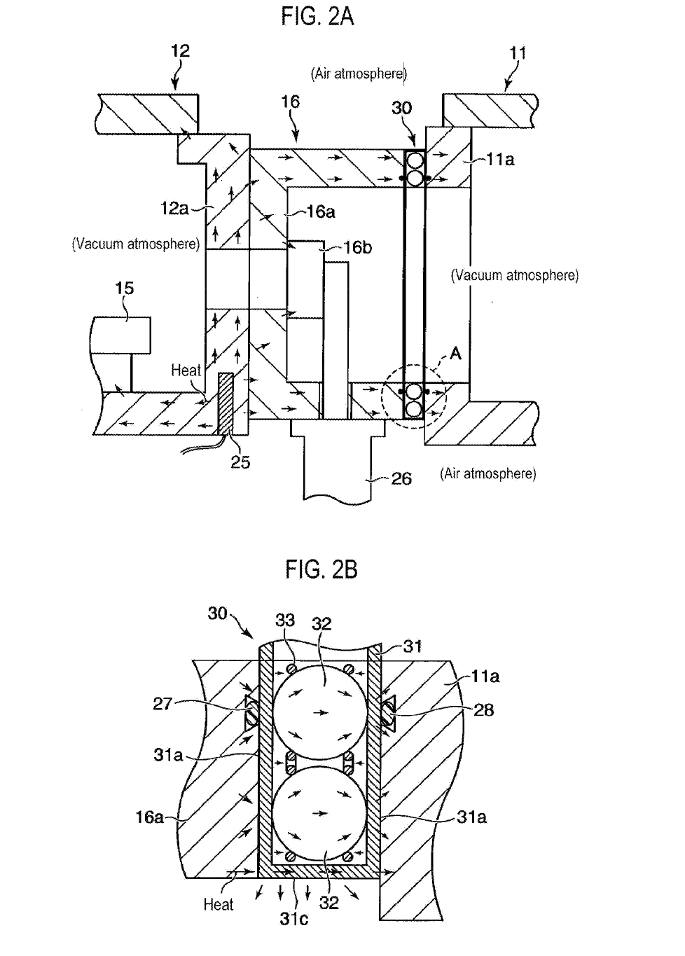

The process module 12 includes a vacuum chamber 12a (see FIG. 2A). A cylinder-shaped stage 15 as a mounting table for mounting the wafer W thereon is installed inside the vacuum chamber 12a. In the process module 12, after the wafer W is mounted on the stage 15, the interior of the vacuum chamber 12a is set to a predetermined degree of vacuum. Then, a process gas is introduced and high frequency power is applied into the vacuum chamber 12a to generate plasma, so that a plasma process, such as an etching process and so forth, is performed upon the wafer W by the generated plasma. The process module 12 and the transfer module 11 are partitioned by a gate valve 16 to be opened and closed.

In the stage 15 included in the process module 12, a plurality of thin stick-shaped elevating pins 15a (three pins in the embodiment) is installed to be protrudable from the upper surface of the stage 15. The elevating pins 15a are arranged concyclically in a plan view which protrude from the upper surface of the stage 15 to support and lift up the wafer W loaded in the stage 15, and are retracted into the stage 15 to thereby mount the supported wafer W on the stage 15.

The transfer module 11 is maintained in a vacuum atmosphere of a predetermined degree of vacuum and a first transfer device 17 having two transfer arms 17a of two scalar-arm types is arranged therein. Two transfer arms 17a are respectively configured to be rotatable and extendable, and fork 17b (end effector) as a loading portion where the wafer W is loaded is installed in a leading end thereof. The first transfer arm 17a is movable along a guide rail (not shown) installed in the transfer module 11 and transfers the wafer W between each process module 12 and each load lock module 14.

The load lock module 14 is configured as an internal pressure variable chamber which is switchable between a vacuum atmosphere and an atmosphere of atmospheric pressure. A gate valve 19 for opening and closing a wafer loading/unloading port of a side of the transfer module 11 in the load lock module 14 is installed at a side of the transfer module 11. Further, a gate valve (not shown) for opening and closing a wafer loading/unloading port of a side of the loader module 13 in the load lock module 14, is installed at a side of the loader module 13 in the load lock module 14. A cylinder-shaped stage 18 as a mounding table for mounting the wafer W is arranged inside the load lock module 14. Elevating pins 18a which are equivalent to the elevating pins 15a are installed in the stage 18 to be protrudable from the upper surface of the stage 15.

At first, when transferring the wafer W from the loader module 13 to the transfer module 11, the load lock module 14 receives the wafer W from the loader module 13 while its interior is maintained at atmospheric pressure, and then passes the wafer W to the transfer module 11 while the interior is depressurized. On the contrary, when transferring the wafer W from the transfer module 11 to the loader module 13, the load lock module 14 first receives the wafer W from the transfer module 11 while the interior is maintained in a vacuum, and then passes the wafer W to the loader module 13 while the interior is pressurized to atmospheric pressure.

The loader module 13 is configured as an atmospheric transfer chamber of a rectangular shape. The load lock module 14 is connected to one side in a longitudinal direction. A plurality of FOUP mounting tables 21 (three in the embodiment) for mounting FOUPs (not shown), which are containers for accommodating a plurality of the wafer W, is connected to the other side of the longitudinal direction.

A second transfer device 20 which transfers the wafer W is disposed inside the loader module 13. The second transfer device 20 has a transfer arm 20a of a scalar arm type. The transfer arm 20a is configured to be rotatable while moving along the guide rail (not shown), and to be extensible and contractible. Similar to the first transfer device 17, a fork 20b for loading the wafer is installed at a leading end of the transfer arm 20a. In the loader module 13, the second transfer device 20 transfers the wafer W between the FOUP mounted in the FOUP mounting table 21 and each of the load lock modules 14. Operation control of the substrate processing device 10 is performed by a controller 22.

Next, a coupling structure of the transfer module 11 and the process module 12 will be explained. FIG. 2A is a cross-sectional view schematically illustrating a structure of a coupling part between a transfer module and a process module, which are included in the substrate process device in FIG. 1. FIG. 2B is an enlarged view of the region A illustrated in FIG. 2A. Heat flow is represented by arrows in FIGS. 2A and 2B.

A heater 25 for uniformly maintaining a temperature of the vacuum chamber 12a constituting the process module 12 is buried in the vacuum chamber 12a in order to prevent reaction products of the process gas or deposition generated during the process of the wafer W from being attached to the vacuum chamber 12a. As described above, the gate valve 16 is arranged between the transfer module 11 and the process module 12. The gate valve 16 includes a cylindrical housing part 16a (hereinafter, referred to as gate valve housing part 16a) connected to the vacuum chamber 12a and a lid part 16b for opening and closing a wafer loading/unloading port of the vacuum chamber 12a. The lid part 16b is movable between a position opening the wafer loading/unloading port and a position closing the wafer loading/unloading port by an elevating device 26.

Some of the heat for heating and keeping the vacuum chamber 12a warm by the heater 25 is transferred toward a housing part 11a which constitutes the transfer module 11 (hereinafter, referred to as a transfer module housing part 11a) through the gate valve housing part 16a. Moreover, since most of the heat transferred from the gate valve housing part 16a to the lid part 16b is transferred to the elevating device 26, the gate valve housing part 16a may be seen as being responsible for heat transfer from the vacuum chamber 12a of the process module 12 to the transfer module housing part 11a.

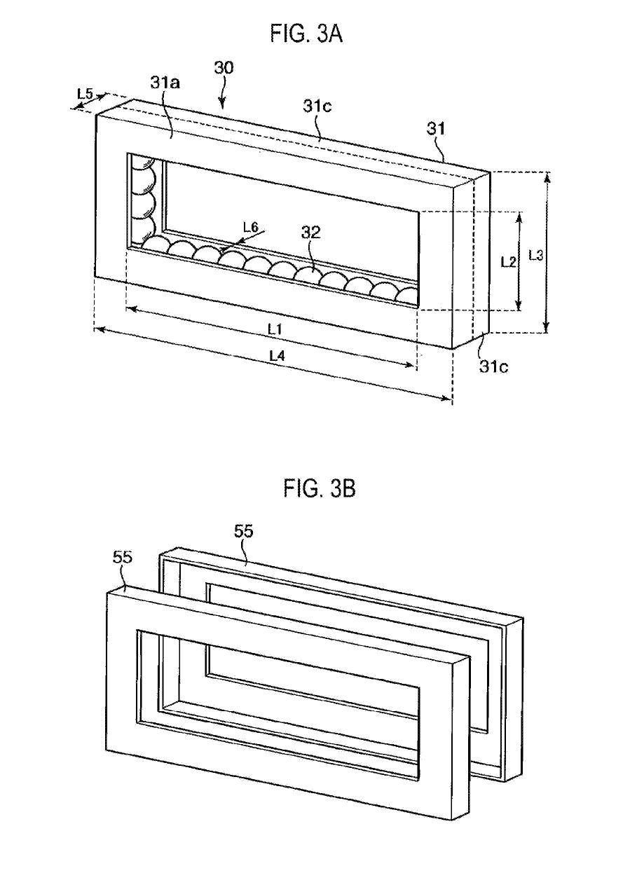

In order to suppress the heat transfer from the gate valve housing part 16a to the transfer module housing part 11a, a coupling member 30 is provided between the gate valve housing part 16a and the transfer module housing part 11a. FIG. 3A is a perspective view schematically illustrating the structure of the coupling member 30 illustrated in FIGS. 2A and 2B. Moreover, FIG. 3B is an exploded perspective view schematically illustrating a frame member 31 which constitutes the coupling member 30 illustrated in FIGS. 2A to 2B.

The coupling member 30 has a frame shape matched to an abutting surface shape of the gate valve housing part 16a and the transfer module housing part 11a. The coupling member 30 includes a frame member 31 of a frame shape, spherical members 32 disposed in the frame member 31, and a retainer 33 which holds the spherical members 32.

L1 to L6 shown in FIG. 3A are dimension parameters which represents the shape of the frame member 31. When a diameter of the wafer is Φ300 mm, for example, length L1 of a long side of the inner hole, length L2 of a short side of the inner hole, external height L3 and external width L4 which are provided in the frame member 31 may be 320 mm, 100 mm, 200 mm and 400 mm, respectively. Further, thickness L5 at the outside of the frame member 31 (thickness of the coupling member 30) is determined by considering desired insulation properties, and plate thickness L6 is determined by considering desired mechanical strength, manufacturing condition (ease of manufacturing) or the like. Further, recently, a wafer W which has a diameter of Φ450 mm is also used to manufacture semiconductor devices. The shape of the frame member 31 is designed in accordance with the shape of the wafer W.

The frame member 31 is made of metallic material such as stainless (SUS304 and so forth) and so forth, and is constituted with two sheet metal members 55 of the same shape, each sheet metal member 55 having a hole portion matched to the side shapes of the gate valve housing part 16a and the transfer module housing part 11a in a peripheral surface as illustrated in FIG. 3B. The frame member 31 is formed by strongly joining the contact portion by laser-arc hybrid welding while touching opening surfaces of two sheet metal members 55 to each other. The plate thickness of the sheet metal member 55, i.e., the plate thickness L6 specifically ranges about from 0.5 mm to 1 mm.

The inner surface of the frame member 31 is exposed to a vacuum atmosphere which is an internal atmosphere of the transfer module. For that reason, the inner surface of the frame member 31 is finished with a mirror surface so as to suppress generation of emission gas, such as moisture and the like, from the inner surface of the frame member. Moreover, as the sheet metal member 55 is finished with the mirror surface, heat radiation can be suppressed, whereby a rise in temperature of the interior of the transfer module 11 can be suppressed. Further, with respect to the inner surface of the sheet metal member 55, mirror surface finishing can be easily performed in a state before joining.

The spherical members 32 increase the mechanical strength of the frame member 31. At that time, the spherical members 32 are formed by appropriately using a member made of material having high rigidity and low thermal conductivity, e.g., zirconia ball so as to suppress heat transfer through the spherical members 32 from the side of the gate valve housing part 16a to the side of the transfer module housing part 11a. However, it is not limited thereto. Metals having low thermal conductivity, for example, a member made of stainless (SUS304, SUS440C and so forth) may be used.

The spherical members 32 are frictionally held and supported in a point contact with the inner surface of the frame member 31 while being held and supported in the retainer 33. Since a contact area of the inner surface of the frame member 31 and the spherical members 32 is small, heat transfer from the side of the gate valve housing part 16a to the spherical members 32 and heat transfer from the spherical members 32 to the side of the transfer module housing part 11a are suppressed. Therefore, a temperature rise of the transfer module housing part 11a can be suppressed.

If the retainer 33 can hold and support the spherical members 32 without being dropped therefrom, the structure thereof is not limited. For example, a structure, in which metal rings having a slightly shorter diameter than that of the spherical members 32 and disposed to face each other in parallel so as to hold and support the spherical members 32 are connected according to the arrangement of the spherical members 32, may be used as the retainer 33 (see, FIG. 2B). Moreover, metal boards of a frame shape, which can be accommodated in the frame member 31 and have a hole portion for frictionally holding and supporting the spherical members 32, can be used.

The coupling member 30 is interposed and supported between the transfer module housing part 11a and the gate valve housing part 16a to separate the vacuum atmosphere of the interior of the transfer module 11 (including the vacuum atmosphere of the interior of the gate valve housing part 16a in the following description.) and an air atmosphere of the exterior of the substrate processing device 10. As shown in FIG. 2B, the coupling member 30 is provided that such that one side of two main surface portions 31a, which face to each other in the frame member 31, makes contact with a side of the gate valve housing part 16a and an O-ring 27 provided at the side of the gate valve housing part 16a by compressing the O-ring 27. The other side of two main surface portions 31a makes contact with a side of the transfer module housing part 11a and an O-ring 28 provided at the side of the transfer module housing part 11a and compresses the O-ring 28. In this way, the vacuum atmosphere of the interior of the transfer module 11 and the air atmosphere of the exterior of the substrate processing device 10 are separated.

In the coupling member 30, thermal conduction from the gate valve housing part 16a to the transfer module housing part 11a is generated through a side portion 31c of the frame member 31. Since the frame member 31 is made of a thin wall of metal material, it is possible to suppress a small amount of heat transfer from the gate valve housing part 16a to the transfer module housing part 11a through the frame member 31. Moreover, the coupling member 30 is provided such that the side portion 31c of the frame member 31 is disposed to be outside of the gate valve housing part 16a and the transfer module housing part 11a, so that, since heat dissipation from the side portion 31c to the exterior of the substrate processing device 10 is performed, it is possible to reduce heat transfer toward the transfer module housing part 11a. Therefore, a temperature rise of the interior of the transfer module housing part 11a can be suppressed.

In the coupling member 30, lack of mechanical strength derived by forming the frame member 31 using a thin metal member is supplemented by the spherical members 32. In other words, the coupling member 30 is interposed and supported while receiving compressive stress from the transfer module housing part 11a and the gate valve housing part 16a, and the spherical members 32 are in point-contact with the inner surface of the frame member 31 which constitutes the coupling member 30. Here, it is well known that the spherical members 32 have high-compressive strength. Therefore, when the spherical members 32 receive compressive stress applied to the coupling member 30 via the frame member 31, a mechanical strength (compressive strength), which is needed for the coupling member 30, is secured by the spherical members 32.

Moreover, the heat transfer from the frame member 31 to the spherical members 32 can be suppressed by having the spherical members 32 be in point-contact with the inner surface of the frame member 31. Further, since the spherical members 32 are exposed to a vacuum atmosphere in order not to generate convection around the spherical members 32, influence of heat dissipation from the spherical members 32 can be suppressed. Moreover, it is possible to suppress the heat transfer from the gate valve housing part 16a to the transfer module housing part 11a through the spherical members 32 by using a material with low-thermal conductivity for the spherical member, whereby it is possible to suppress a temperature rise of the transfer module housing part 11a.

Since the coupling member 30 includes a plurality of the spherical members 32, an area adding total surface area of the spherical members 32 exposed to vacuum atmosphere of the transfer module 11 to an inner area of the frame member 31 becomes larger than an area of a surface exposed to the vacuum atmosphere of the interior of the transfer module 11 in a coupling member using conventional PEI resin bulk. However, radiant heat from the frame member 31 and the spherical members 32 is smaller than radiant heat from the coupling member using PEI resin bulk due to the difference in heat radiation ratio of the materials. Therefore, a temperature rise in the interior of the transfer module 11 can be suppressed rather than the case of using the coupling member made of conventional PEI resin bulk by using the coupling member 30.

Moreover, since the coupling member 30 is made of stainless steel or a zirconia ball, not PEI resin, the generation amount of gas emission such as moisture and so forth is smaller than PEI resin, whereby contamination of the interior of the transfer module 11 can be prevented. Further, the coupling member 30 can be made by using inexpensive stainless steel or a zirconia ball, which is inexpensive, rather than the expensive PEI resin, whereby cost reduction of the coupling member 30 can be expected.

Moreover, the O-rings 27 and 28 are disposed at a position facing across the spherical members 32 while interposing the main surface portions 31a of the frame member 31 therebetween. In this way, as the O-rings 27 and 28 make contact with portions showing high compressive strength in the coupling member 30, sealability can be improved by the O-rings 27 and 28. Here, in the coupling member 30 illustrated in FIGS. 2A, 2B, 3A and 3B, whereas the spherical members 32 are disposed in two rows at a column, the O-rings 27 and 28 are disposed one by one to face across the inner spherical members 32, respectively. However, the disposition of the O-rings 27a and 28b is not limited thereto. The O-rings 27 and 28 may be disposed to face across the outer spherical members 32. Further, the O-rings 27 and 28 may be dual rings of an inner ring and an outer ring to match the inner and outer spherical members 32. The spherical members 32 may be disposed in one row, in that case, the O-rings 27 and 28 may be disposed to face across the spherical members 32 of one row.

Hereinafter, amounts of heat transferred by the coupling member made of conventional PEI resin (bulk) and the coupling member 30 are compared below by setting them to have shapes which can pass a wafer W having a diameter of Φ450 mm. The lengths L1 to L4 illustrated in FIG. 3A are set such that the length L1 of a long side of the inner hole is 500 mm, the length L2 of a short side of the inner hole is 63 mm, the external height L3 is 162 mm, and the external width is 600 mm Moreover, the plate thickness (thickness) L6 of the frame member 31 is 0.5 mm. Further, the amount of heat transferred by the spherical members 32 is assumed to be negligible with respect to the amount of heat transferred by the frame member 31.

A heat transfer area S1 of the coupling member made of PEI resin becomes “S1=600×162−500×63=65700”, and a heat transfer area S2 of the coupling member 30 becomes “S2=600×162−599×161=761”. Heat conductivity K1 of the PEI resin is 0.22 W/m·k. If the frame member 31 is configured with SUS304, heat conductivity K2 of SUS304 is 16.2 W/m·k.

An amount of heat transferred, Q, can be represented as “Q=K×S×t×(T0−T1)/L5 (here, K: heat conductivity, S: heat transfer area, t=time, T0: heat transfer upstream temperature, T1: heat transfer downstream temperature, and L5: thickness of coupling member (see, FIG. 3A))”. The coupling member made of PEI resin and the coupling member 30 have the same values except “K×S.” Thus, if the value of “K×S” is small, it is assumed that the amount of heat transferred is small. In the case of the PEI resin, “K×S” becomes “K×S=K1×S1=14454”, and in the case of the coupling member 30, “K×S” becomes “K×S=K2×S2=12328”. Therefore, it makes it possible to suppress the heat transfer at a small amount by the coupling member 30 as compared with the coupling member made of PEI resin.

Next, a modified example of the coupling member 30 will be explained. Herein, With respect to the modified example, same reference numerals are given to the same members as those of the members constituting the coupling member 30.

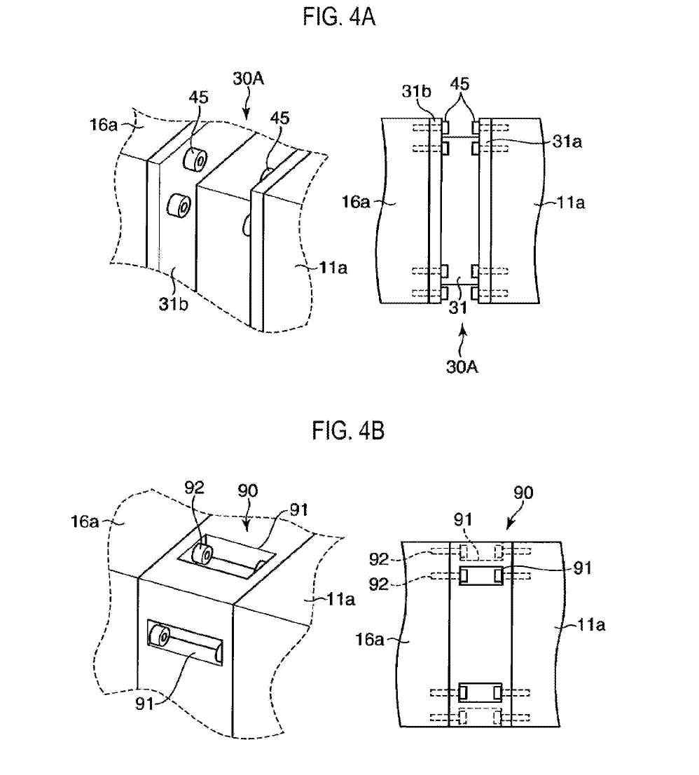

FIG. 4A is a partial perspective view and a side view of coupling member 30A, which is a first modified example of the coupling member 30 according to the embodiment of the present disclosure. The coupling member 30A has a flange portion 31b formed by extending a main surface portion 31a of the coupling member 30 toward the outer peripheral portion, and shows a flange structure that the entire coupling member 30A is installable by a bolt 45 with respect to the transfer module housing part 11a and the gate valve housing part 16a.

Since the coupling member 30A has a flange structure, it is easy to determine the location of the coupling member 30A with respect to the transfer module housing part 11a and the gate valve housing part 16a. Moreover, since a strong coupling of the transfer module housing part 11a and the gate valve housing part 16a can be performed by the bolt 45, separation of the vacuum atmosphere of the interior of the transfer module 11 and the air atmosphere of the exterior of the substrate processing device 10 can be performed more reliably. Further, like the coupling member 30, an amount of heat transferred is reduced as compared with the coupling member made of PEI resin, so that a temperature rise of the interior of the transfer module 11 can be suppressed, and it makes it possible to inexpensively manufacture.

FIG. 4B shows a partial perspective view and a side view of a coupling member having a flange structure and made of the PEI resin as a comparative example of the coupling member 30 according to the embodiment of the present disclosure. The coupling member 90 has a structure in which concave portions 91 are formed at an outer surface of the PEI resin bulk having a frame shape, and bolts 92 from the concave portions 91 are screwed into screw holes formed in the transfer module housing part 11a and the gate valve housing part 16a. However, since the thickness of the portions where the bolts 92 are inserted through the PEI resin bulk is thin, the bolt 92 cannot be joined strongly, whereby strong coupling, similar to the coupling member 30A, with respect to the transfer module housing part 11a and the gate valve housing part 16a cannot be secured.

Moreover, if the flange portion is installed in the coupling member made of PEI resin like the flange portion 31b of the coupling member 30A, there is a problem that the flange portion (root portion thereof) can easily break due to the small mechanical strength of the flange portion. Thus, it is difficult to employ the flange structure in the coupling member made of PEI resin.

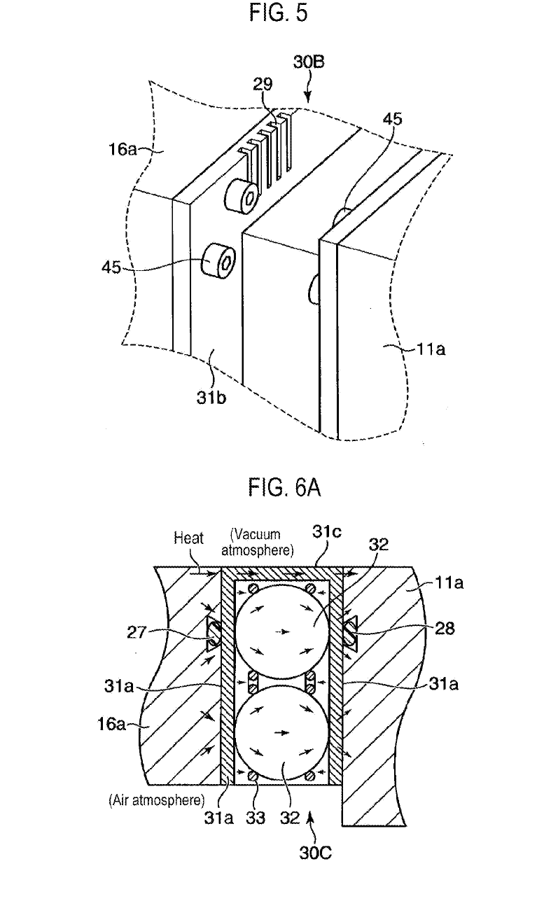

FIG. 5 is a partial perspective view of a coupling member 30B which is a second modified example of the coupling member 30 according to the embodiment of the present disclosure. In the coupling member 30, the flange portion 31b is used as a radiation fin by forming notches 29 in the flange portion 31b included in the coupling member 30A. In this way, the coupling member 30B has a structure that heat transferred from the side of the gate valve 16 to the side of the transfer module 11 is easily emitted into the air atmosphere of the external of the substrate processing device 10. Therefore, by the coupling member 30B, an amount of heat transferred in the coupling member 30B from the gate valve housing part 16a to the transfer module housing part 11a can be reduced, so that a temperature rise in the internal portion of the transfer module 11 can be suppressed. Of course, the coupling member 30B has an advantage in that it is possible to inexpensively manufacture like the coupling members 30 and 30A as compared with the coupling member made of conventional PEI resin.

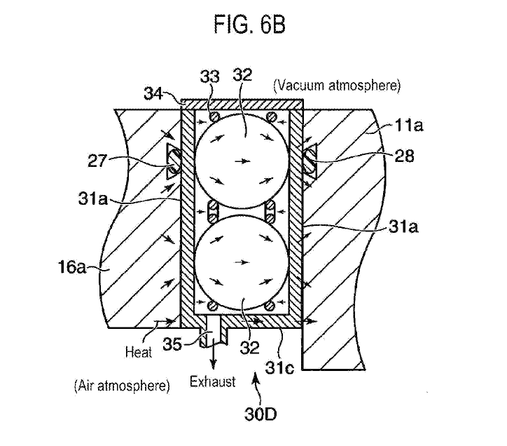

FIG. 6A is a partial cross-sectional view of coupling member 30C which is a third modified example of the coupling member 30 according to the embodiment of the present disclosure, and corresponds to FIG. 2B. In the coupling members 30 to 30B, the spherical members 32 are configured to be exposed to a vacuum atmosphere of the interior of the transfer module 11. Contrary to this configuration, the coupling member 30C has a structure that the spherical members 32 are exposed to the air atmosphere of the exterior of the substrate processing device 10.

In the coupling member 30C, the side portion 31c, which becomes a heat transfer path in the frame member 31, is disposed to be located in an inner side of the gate valve housing part 16a and the transfer module housing part 11a. In this way, as the area of the coupling member 30C, which is exposed to the vacuum atmosphere of the interior of the transfer module 11, becomes small, the generation amount of the gas emission can lessen greatly. Moreover, in some embodiments, the surface of the side of the vacuum atmosphere of the side portion 31c is formed with a mirror surface.

Further, in the coupling member 30C, since the area in the frame member 31, which is exposed to the air atmosphere is large and the spherical members 32 are exposed to the air atmosphere, the amount of heat dissipation from the frame member 31 and the spherical members 32 to the air atmosphere is increased. Thus, an amount of heat transferred at the side portion 31c of the frame member 31 is reduced, thereby suppressing a temperature rise of the internal portion of the transfer module 11.

The coupling member 30C has a structure easy to manufacture and can be firmly assembled by bolts with respect to the transfer module housing part 11 a and the gate valve housing part 16a by using the main surface portion 31a of the frame member 31 (not shown) as the flange portion 31b of the coupling member 30A. Moreover, it is easy to form a radiation fin by forming notches in the main surface portion 31a like the coupling member 30B in the coupling member 30C, so that an efficiency of the radiant heat can be increased. Further, the coupling member 30C can suppress a temperature rise of the internal of the transfer module 11 by reducing the amount of heat transferred and can be manufactured inexpensively like the coupling members 30 to 30B as compared with the coupling member made of the conventional PEI resin.

FIG. 6B is a partial cross-sectional view of coupling member 30D which is a fourth modified example of the coupling member 30 according to the embodiment of the present disclosure, and corresponds to the FIG. 2B. The coupling member 30D has a structure enclosing the spherical members 32 by closing an opening surface in the side of the vacuum atmosphere in the coupling member 30D with a lid member 34. Moreover, as an exhaust port 35 is formed in the side portion 31c of the air atmosphere side facing the lid member 34 to thereby perform exhaust of a space, where the spherical members 32 are disposed, from the exhaust port 35, the coupling member 30D is structured to maintain the space in a predetermined degree of vacuum.

In the coupling member 30D, the lid member 34 and the side portion 31c become a heat transfer route from the gate valve housing part 16a to the transfer module housing part 11a. By controlling the degree of vacuum of the space where the spherical members 32 are disposed, or by forming the surface of the lid member 34, which is exposed to the vacuum atmosphere of the interior of the transfer module 11, with a mirror surface, heat radiation can be controlled.

Moreover, since an area exposed to the vacuum atmosphere is just an area of the lid member 34 in the coupling member 30D, as compared with the coupling members 30 to 30B, emission gas can be lessened. In addition, inexpensive manufacture is possible like the coupling members 30 to 30C, as compared with the coupling member made of conventional PEI resin. Further, by reducing an amount of heat transferred, a temperature rise of the interior of the transfer module 11 can be suppressed.

While the embodiments of the present disclosure have been described, the present disclosure is not limited to the embodiments. The present disclosure may be embodied in structure so that the embodiments are combined. Moreover, for example, in the embodiments, while the spherical members 32 were used so that the coupling member 30 and so forth has mechanical strength, it may not be limited thereto. Pillar-shaped members such as cylindrical pillars, square pillars and so forth, honeycombs, cone-shape members, or square pillar-shape members may be used. Further, since the spherical members 32 are in point-contact with the frame member 31, if it is considered that the heat transfer between the spherical members 32 and the frame member 31 can be suppressed or cost can be suppressed by using general product, alumina, silicon nitride, silicon carbide, SUJ (chrome steel) and so forth may be used as the spherical members 32.

In the embodiments, although the vacuum chamber 12a and the gate valve housing part 16a are structurally distinguished, the gate valve housing part 16a may be configured as a part of the vacuum chamber 12a. In this case, the coupling member 30 and so forth connect the vacuum chamber 12a and the transfer module housing part 11a. Moreover, in the embodiments, although one of the coupling members 30 to 30D is disposed between the transfer module housing part 11a and the gate valve housing part 16a, a plurality of coupling members 30 to 30D are disposed to be arranged in a direction coupling the transfer module housing part 11a and the gate valve housing part 16a.

Moreover, in the embodiments, although a plasma processing device was explained as the substrate processing device, it may not be limited thereto. The present disclosure may be applied to a variety of devices including a processing chamber having higher temperature than room temperature and a transfer chamber loading/unloading substrates with respect to the processing chamber. Further, in the embodiments, although a semiconductor wafer was explained as substrate, it may not be limited thereto. An object to be transferred may be other substrates such as glass substrates used for a flat panel display (FPD), ceramic substrates and so forth.

This application claims the benefit of Japanese Patent Application No. 2013-066104, filed on Mar. 27, 2013, in the Japan Patent Office, the disclosure of which is incorporated herein in its entirety by reference.

### EXPLANATION OF REFERENCE NUMERALS

10: substrate processing device, 11: transfer module, 11a: transfer module housing part, 12: process module, 12a: vacuum chamber, 14: load lock module, 16: gate valve, 16a: gate valve housing part, 17: first transfer device, 27 and 28: O-ring, 29: notch, 30, 30a, 30B, 30C and 30d: coupling member, 31: frame member, 31a: main surface portion, 31b: flange portion, 31c: side surface portion, 32: spherical member (zirconia ball), 33: retainer, 55: sheet metal member

1. A substrate processing device comprising:
a processing chamber maintained in a vacuum atmosphere to process a substrate;
a transfer chamber configured to transfer the substrate to/from the processing chamber; and
a coupling member configured to connect the processing chamber and the transfer chamber,
wherein the coupling member comprises:
a metallic frame member interposed and supported between a housing part of the processing chamber and a housing part of the transfer chamber, and that separates an interior of the transfer chamber having a vacuum atmosphere and an exterior of the substrate processing device having an air atmosphere; and
a plurality of spherical members that are in contact with an inner surface of the frame member in an interior of the frame member, the plurality of spherical members made of metal or ceramics.

2. The substrate processing device of claim 1, wherein a temperature of the processing chamber is higher than room temperature.

3. The substrate processing device of claim 1, wherein the frame member is made of stainless steel having a thickness ranging from 0.5 to 1 mm.

4. The substrate processing device of claim 1, wherein the spherical members are zirconia balls or stainless balls.

5. The substrate processing device of claim 1, wherein, in the frame member, a surface exposed to the vacuum atmosphere of the interior of the transfer chamber is a minor surface.

6. The substrate processing device of claim 1, wherein, in the coupling member, the spherical members are exposed to the vacuum atmosphere of the interior of the transfer chamber.

7. The substrate processing device of claim 1, wherein, in the coupling member, the spherical members are exposed to the air atmosphere of the exterior of the substrate processing device.

8. The substrate processing device of claim 1, wherein the coupling member comprises a lid member that encloses the spherical members in the frame member;
wherein the frame member comprises an exhaust port to evacuate a space enclosing the spherical member; and
wherein the space enclosing the spherical members has a predetermined degree of vacuum.

9. The substrate processing device of claim 1, wherein the frame member comprises a flange portion fixed to the processing chamber and the transfer chamber by bolts.

10. A coupling member for a substrate processing device including a processing chamber maintained in a vacuum atmosphere to process a substrate, a transfer chamber maintained in vacuum atmosphere to transfer the substrate to/from the processing chamber, the coupling member coupling the processing chamber and the transfer chamber, the coupling member comprising:
a metallic frame member interposed and supported between a housing part of the processing chamber and a housing part of the transfer chamber, and that separates an interior of the transfer chamber having a vacuum atmosphere and an exterior of the substrate processing device having an air atmosphere; and
a plurality of spherical members that are in contact with an inner surface of the frame member in an interior of the frame member.

11. The coupling member of claim 10, wherein the frame member is made of stainless steel having a thickness ranging from 0.5 to 1 mm.

12. The coupling member of claim 10, wherein the spherical members are zirconia balls or stainless balls.
